(19) United States
(12) Patent Application Publication
(10) Pub. No.: US 2024/0194639 A1
(43) Pub. Date: Jun. 13, 2024

(54) SEMICONDUCTOR PACKAGE

(71) Applicant: SAMSUNG ELECTRONICS CO., LTD., Suwon-si (KR)

(72) Inventors: Sang Cheon PARK, Suwon-si (KR); Chungsun Lee, Suwon-si (KR); Soohwan Lee, Suwon-si (KR); Young Kun Jee, Suwon-si (KR)

(73) Assignee: SAMSUNG ELECTRONICS CO., LTD., Suwon-si (KR)

(21) Appl. No.: 18/220,053

(22) Filed: Jul. 10, 2023

(30) Foreign Application Priority Data
Dec. 13, 2022 (KR) 10-2022-0173264

(51) Int. Cl. H01L 25/065; H01L 23/00; H01L 23/31; H01L 23/498; H01L 23/538; H10B 80/00

(52) U.S. Cl. CPC H01L 25/0652; H01L 23/3128; H01L 23/49811; H01L 23/5385; H01L 24/05; H01L 24/08; H01L 24/80; H10B 80/00; H01L 2224/05647; H01L 2224/08145; H01L 2224/08225; H01L 2224/80379

(57) ABSTRACT

Provided is a semiconductor chip stack structure including a plurality of first semiconductor chip dies stacked in a vertical direction, and one or more second semiconductor chip dies between adjacent first semiconductor chip dies among the plurality of first semiconductor chip dies, wherein a thickness of each second semiconductor chip die of the one or more second semiconductor chip dies is greater than a thickness of each first semiconductor chip die of the plurality of first semiconductor chip dies in the vertical direction.

### CROSS-REFERENCE TO RELATED APPLICATION

This application claims priority to Korean Patent Application No. 10-2022-0173264 filed in the Korean Intellectual Property Office on Dec. 13, 2022, the disclosure of which is incorporated herein in its entirety by reference.

### BACKGROUND

### 1. Field

Embodiments of the present disclosure relate to a semiconductor package.

### 2. Description of Related Art

In the semiconductor industry, in line with the demand for miniaturization and weight reduction of electronic devices, semiconductor packages mounted on electronic devices are being miniaturized, lightweight, and thinned, while at the same time pursuing high-speed, multifunctional, and high-capacity semiconductor packages. Therefore, there is an increasing need for packaging technology capable of storing more data and transmitting data at a higher speed, and as the packaging technology, a high bandwidth memory (HBM) capable of achieving a high level of bandwidth by stacking more memory devices such as dynamic random-access memories (DRAMs) on a board having the same area is well known.

When hybrid bonding technology is applied to stacking DRAMs of the HBM, in the upper part of the HBM, a stack void may be generated at an interface between DRAM dies as a result of the accumulation of surface topography of each DRAM stack.

Therefore, it is necessary to develop a new package technology capable of preventing the generation of stack voids in the HBM to which the hybrid bonding technology is applied.

### SUMMARY

In a high-bandwidth memory (HBM) in which memory dies are bonded and stacked by applying a hybrid bonding technology, a stack void may be generated at an interface between the memory die and the memory die at an upper end of the HBM as a result of the accumulation of the surface topography of each memory die. The present disclosure is directed to providing a semiconductor chip stack structure and a semiconductor package capable of preventing the formation of stack voids by disposing thick memory dies between memory dies.

According to an aspect of an embodiment, there is provided a semiconductor chip stack structure including a plurality of first semiconductor chip dies stacked in a vertical direction, and one or more second semiconductor chip dies between adjacent first semiconductor chip dies among the plurality of first semiconductor chip dies, wherein a thickness of each second semiconductor chip die of the one or more second semiconductor chip dies is greater than a thickness of each first semiconductor chip die of the plurality of first semiconductor chip dies in the vertical direction.

According to another aspect of an embodiment, there is provided a semiconductor package including an interposer, a plurality of semiconductor chip stack structures on the interposer, each semiconductor chip stack structure of the plurality of semiconductor chip stack structures including a plurality of first semiconductor chip dies stacked in a vertical direction and one or more second semiconductor chip dies between adjacent first semiconductor chip dies among the plurality of first semiconductor chip dies, a third semiconductor chip on the interposer, and an encapsulant on the interposer, the plurality of semiconductor chip stack structures, and the third semiconductor chip, wherein a thickness of each second semiconductor chip die of the one or more second semiconductor chip dies is greater than a thickness of each first semiconductor chip die of the plurality of first semiconductor chip dies in the vertical direction.

According to another aspect of an embodiment, there is provided a semiconductor package including a substrate, an interposer on the substrate, a plurality of connection members electrically connecting the substrate and the interposer, a plurality of semiconductor chip stack structures directly on the interposer, each of the semiconductor chip stack structures of the plurality of semiconductor chip stack structures including a plurality of first semiconductor chip dies stacked in a vertical direction and one or more second semiconductor chip dies between adjacent first semiconductor chip dies among the plurality of first semiconductor chip dies, a third semiconductor chip on the interposer, and an encapsulant disposed on the interposer, the plurality of semiconductor chip stack structures, and the third semiconductor chip, wherein a thickness of each second semiconductor chip die of the one or more second semiconductor chip dies is greater than a thickness of each first semiconductor chip die of the plurality of first semiconductor chip dies in the vertical direction.

### BRIEF DESCRIPTION OF DRAWINGS

The above and other aspects, features, and advantages of embodiments will be more apparent from the following description taken in conjunction with the accompanying drawings, in which:

FIG. 1 is a cross-sectional view illustrating accumulated surface topography of a semiconductor chip stack when the semiconductor chip stack is formed of 12H-semiconductor chip dies in High-Bandwidth Memory (HBM) including a semiconductor chip stack in which a plurality of 12H-semiconductor chip dies is directly bonded to each other and stacked by applying a hybrid bonding technology;

FIG. 2 is a graph illustrating deviation values of surface topography measured in a semiconductor chip die before performing a wafer thinning process, and an 8H-semiconductor chip die, a 12H-semiconductor chip die, and a 16H-semiconductor chip die after performing a wafer thinning process;

FIG. 3 is a cross-sectional view illustrating an HBM including a semiconductor chip stack in which a stack void is formed in a high-stage stack of FIG. 1, and a graph illustrating deviation values of surface topography corresponding to each 12H-semiconductor chip die of an HBM including the semiconductor chip stacks in which stack voids are formed in the high-stage stack;

FIG. 4 is a graph illustrating measured values of void ratios according to the number of stacked layers of a 12H-semiconductor chip die in an HBM;

FIG. 5 is a cross-sectional view illustrating an HBM in which 8H-semiconductor chip dies are interposed between stacked 12H-semiconductor chip dies according to an embodiment, and a graph illustrating deviation values of surface topography corresponding to each 12H-semiconductor chip die and 8H-semiconductor chip die in an HBM in which an 8H-semiconductor chip die is interposed between stacked 12H-semiconductor chip dies;

FIG. 6 is a cross-sectional view illustrating cross-sections of a 12H-semiconductor chip die, an 8H-semiconductor chip die, and a 16H-semiconductor chip die according to an embodiment;

FIG. 7 is a cross-sectional view illustrating an HBM in which 8H-semiconductor chip dies are interposed between stacked 12H-semiconductor chip dies according to an embodiment;

FIG. 8 is a cross-sectional view illustrating an HBM in which a plurality of 8H-semiconductor chip dies is interposed between stacked 12H-semiconductor chip dies according to an embodiment;

FIG. 9 is a cross-sectional view illustrating an HBM in which 12H-semiconductor chip dies and 8H-semiconductor chip dies are alternately stacked according to an embodiment;

FIG. 10 is a cross-sectional view of a 2.5D semiconductor package including an HBM according to an embodiment; and

FIG. 11 is a cross-sectional view illustrating a cross-section of a 3D semiconductor package including the HBM according to an embodiment.

### DETAILED DESCRIPTION

In the following detailed description, only certain embodiments of the disclosure have been illustrated and described, simply by way of illustration. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

In addition, the size and thickness of each configuration illustrated in the drawings are arbitrarily illustrated for understanding and ease of description, but the present disclosure is not limited thereto.

Throughout the specification, when a part is said to be “connected” to another part, this includes not only a case where the parts are “directly connected” but also a case where the parts are “indirectly connected” with another member interposed therebetween. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “on” another element, it can be directly on the other element or intervening elements may also be present.

Further, in the entire specification, when it is referred to as “on a plane” it means when a target part is viewed from above, and when it is referred to as “on a cross-section”, it means when the cross-section obtained by cutting a target part vertically is viewed from the side.

Hereinafter, a semiconductor package of an embodiment will be described with reference to the drawing.

A high-bandwidth memory (HBM) is a high-performance three-dimensional (3D) stacked dynamic random-access memory (DRAM). The HBM is manufactured by using through silicon via (TSV) technology of vertically stacking memory dies including DRAM chips to form a memory stack, forming thousands of fine holes vertically penetrating the stacked memory dies for electrical connecting the memory dies, and filling the fine holes with a conductive material to connect the memory dies with electrodes.

The HBM has multiple memory channels through a memory stack in which memory dies are vertically stacked to implement simultaneously shorter latency and higher bandwidth than DRAM products in the related art, and may have the reduced total area occupied by individual DRAMs on a PCB, so that the HBM is advantageous in terms of high bandwidth compared to area and has the advantage of reducing power consumption.

On the other hand, the HBM has a problem in that it is difficult to stack memory dies above a certain height due to structural limitations of semiconductor packages and the difficulty of stacking technology, and the number of memory dies that can be included per memory stack is limited.

In the HBM, semiconductor chip dies (memory dies) of 8H layers, 12H layers, and 16H layers may be stacked in one memory stack. An 8H-semiconductor chip die may be one memory die among eight memory dies from the 1H layer to the 8H layer stacked to form one memory stack. A vertical thickness of the 8H-semiconductor chip die may be about 55 um. A 12H-semiconductor chip die may be one memory die among 12 memory dies from the 1H layer to the 12H layer stacked to form one memory stack. A vertical thickness of the 12H-semiconductor chip die may be about 38 um. A 16H-semiconductor chip die may be one memory die among 16 memory dies from the 1H layer to the 16H layer stacked to form one memory stack. A vertical thickness of the 16H-semiconductor chip die may be about 27 um. In the present disclosure, an HBM stacked with 8H-semiconductor chip dies, 12H-semiconductor chip dies and 16H-semiconductor chip dies is described, but embodiments are not limited thereto.

Semiconductor chip dies of the HBM may be bonded by applying a hybrid bonding process. Hybrid bonding is to bond two devices by fusing the same material of the two devices by using the bonding properties of the same material. Here, the hybrid bonding may include two different types of bonding being performed, for example, bonding two devices with a first type of metal-metal bonding and a second type of non-metal-non-metal bonding.

The semiconductor chip dies may include a plurality of bonding pads on each of an upper surface and a lower surface, and an insulation layer positioned at the same level as the plurality of bonding pads in a horizontal direction. A plurality of bonding pads of one semiconductor chip die is directly bonded to a plurality of bonding pads of an adjacent semiconductor chip die by metal-metal hybrid bonding. At an interface between a plurality of bonding pads of one semiconductor chip die and a plurality of bonding pads of an adjacent semiconductor chip die, metal bonding is performed by heat and pressure. An insulation layer of one semiconductor chip die is directly bonded to an insulation layer of an adjacent semiconductor chip die by non-metal-non-metal hybrid bonding. At the interface between an insulation layer of one semiconductor chip die and an insulation layer of an adjacent semiconductor chip die, covalent bonding is formed by heat and pressure.

In this way, when semiconductor chip dies are bonded by hybrid bonding, a multi-level stack may be formed without using solder balls, and wire connection may be made with a very small bonding pitch.

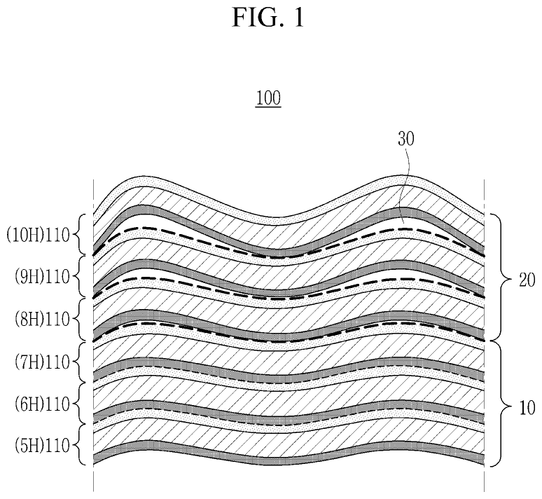

FIG. 1 is a cross-sectional view illustrating accumulated surface topography of a semiconductor chip stack when a semiconductor chip stack is formed of 12H-semiconductor chip dies 110 in a high-bandwidth memory (HBM) 100 including a semiconductor chip stack in which a plurality of 12H-semiconductor chip dies 110 are directly bonded to each other and stacked by applying a hybrid bonding technology. In FIG. 1, for convenience, only six 12H-semiconductor chip dies 110 from the 5H layer to the 10H layer are illustrated, and the remaining six 12H-semiconductor chip dies 110 from the 1H layer to the 4H layer, the 11H layer, and the 12H layer are not illustrated.

FIG. 1 illustrates that in a semiconductor chip stack formed by stacking twelve 12H-semiconductor chip dies 110 having a vertical thickness of about 38 pm from a 1H layer to a 12H layer, stack voids are not included at the interfaces between the 12H-semiconductor chip dies 110 of the low-stage stack 10 of the semiconductor chip stack. However, the stack voids 30 may be included at the interfaces between the 12H-semiconductor chip dies 110 of the high-stage stack 20 of the semiconductor chip stack. The stack void 30 may be determined from an image inspected by using scanning acoustic tomography (SAT) equipment.

The stack void 30 in the high-stage stack 20 of the semiconductor chip stack may be generated due to an increase in the accumulated surface topography of the HBM 100 in which the 12H-semiconductor chip dies 110 are stacked, and the stack voids 30 generated in this way may cause a significant increase in the accumulated surface topography of the semiconductor stack. Due to this vicious cycle, the accumulated surface topography of the stacked semiconductor chips may greatly increase, and more stack voids 30 may be formed. The increase in the accumulated surface topography of the stacked semiconductor stack and the stack voids 30 may cause deterioration of etch uniformity during the subsequent TSV formation process and cause bonding failure during the hybrid bonding process, which consequently results in relatively high yield loss.

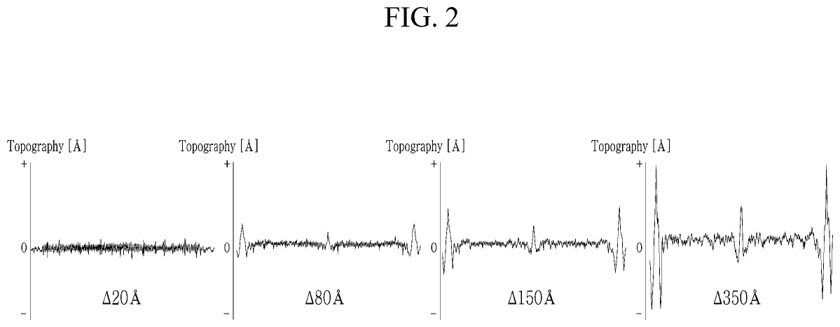

FIG. 2 is a graph illustrating deviation values of surface topography measured in a semiconductor chip die before performing a wafer thinning process, and an 8H-semiconductor chip die, a 12H-semiconductor chip die, and a 16H-semiconductor chip die after performing a wafer thinning process.

FIG. 2 illustrates surface topography deviation of the semiconductor chip die before performing a wafer thin film process on the semiconductor chip die, surface topography deviation of the 8H-semiconductor chip die formed by performing a wafer thin film process on the semiconductor chip die, surface topography deviation of the 12H-semiconductor chip die formed by performing a wafer thin film process on the semiconductor chip die, and surface topography deviation of the 16H-semiconductor chip die formed by performing a wafer thin film process on the semiconductor chip die.

In a process of forming a semiconductor chip stack by performing hybrid bonding, a process of thinning a wafer is performed to form a TSV on a backside of a semiconductor chip die.

The vertical thickness of the semiconductor chip die measured before performing the process of thinning the backside wafer of the semiconductor chip die may be about 775 μm, and the difference between the maximum and minimum values of the surface topography measurement may be about 20 Å.

The vertical thickness of the 8H-semiconductor chip die formed after performing the process of thinning the backside wafer of the semiconductor chip die may be about 55 μm, and the difference between the maximum and minimum values of the surface topography measurement may be about 80 Å.

The vertical thickness of the 12H-semiconductor chip die formed after performing the process of thinning the backside wafer of the semiconductor chip die may be about 38 μm, and the difference between the maximum and minimum values of the surface topography measurement may be about 150 Å.

The vertical thickness of the 16H-semiconductor chip die formed after performing the process of thinning the backside wafer of the semiconductor chip die may be about 27 μm, and the difference between the maximum and minimum values of the surface topography measurement may be about 350 Å.

The vertical thickness of the semiconductor chip die measured without thinning the backside wafer of the semiconductor chip die is about 775 μm and the surface topography deviation is about 20 Å. The vertical thickness of the semiconductor chip die measured after performing the process of thinning the backside wafer of the semiconductor chip die is about 27 μm and the surface topography deviation is about 350 Å. In surface topography deviation of the 16H-semiconductor chip die, the thickness is reduced by about 28 times compared to the semiconductor chip die before performing a wafer thin film process, while the surface topography deviation is increased by about 15 times compared to the semiconductor chip die before performing a wafer thin film process. Therefore, as the thickness of the semiconductor chip die is made thinner to include more semiconductor chip dies in the HBM, the surface topography deviation increases, and the possibility that the stack void 30 is formed in the high-stage stack 20 of the semiconductor chip stack increases.

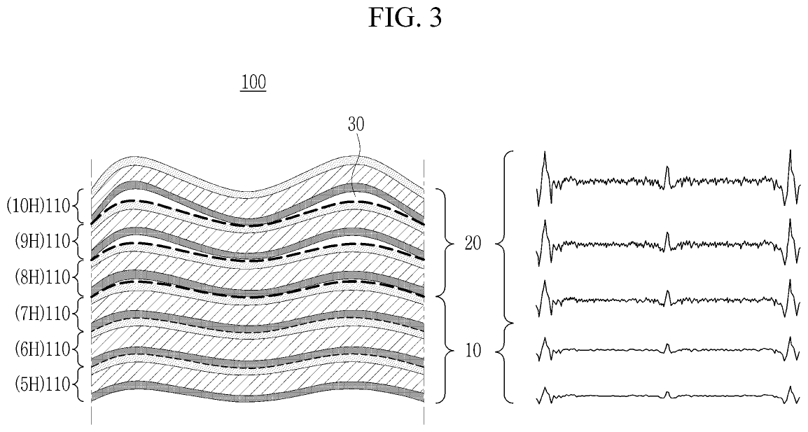

FIG. 3 is a cross-sectional view illustrating an HBM 100 including a semiconductor chip stack in which a stack void 30 is formed in a high-stage stack 20 of FIG. 1, and a graph illustrating deviation values of surface topography corresponding to each 12H-semiconductor chip die 110 of the HBM including the semiconductor chip stacks in which stack voids 30 are formed in the high-stage stack 20.

Referring to FIG. 3, the HBM 100 may include a semiconductor stack in which twelve 12H-semiconductor chip dies 110 having a vertical thickness of 38 μm are stacked from a 1H layer to a 12H layer. The surface topography deviation graph corresponding to the 12H-semiconductor chip die 110 of the 10H layer from the 12H-semiconductor chip die 110 of the 5H layer illustrates that, from the 12H-semiconductor chip die 110 of the 5H layer to the 12H-semiconductor chip die 110 of the 10H layer, the deviation of the surface topography accumulates and increases, and the stack void 30 is better formed.

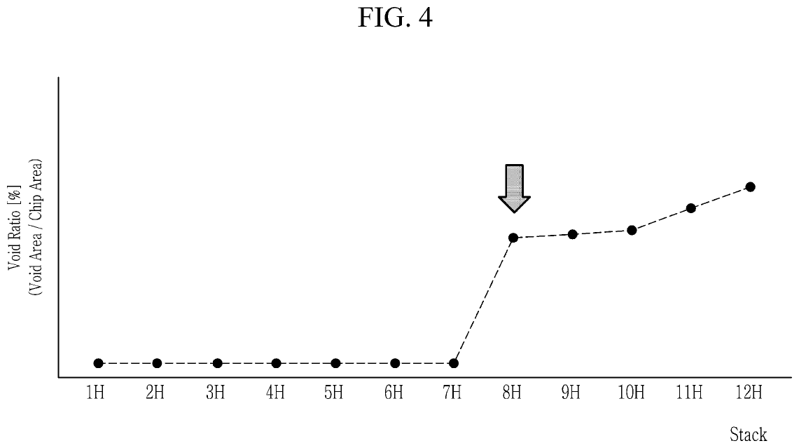

FIG. 4 is a graph illustrating measured values of void ratios according to the number of stacked layers of the 12H-semiconductor chip dies 110 in the HBM.

Referring to FIG. 4, the X-axis represents the number of layers in which the 12H-semiconductor chip dies 110 are stacked, and the Y-axis represents the ratio of the area of the 12H-semiconductor chip dies 110 to the area of the stacked void 30. It can be seen that stack voids are not formed when the 12H-semiconductor chip dies 110 are stacked from the 1H layer to the 7H layer, a stack void 30 starts to be formed in the 8H layer in which one more 12H-semiconductor chip die 110 is stacked, and as the 12H-semiconductor chip dies 110 are stacked from the 9H layer to the 12H layer, the stack void 30 is further increased.

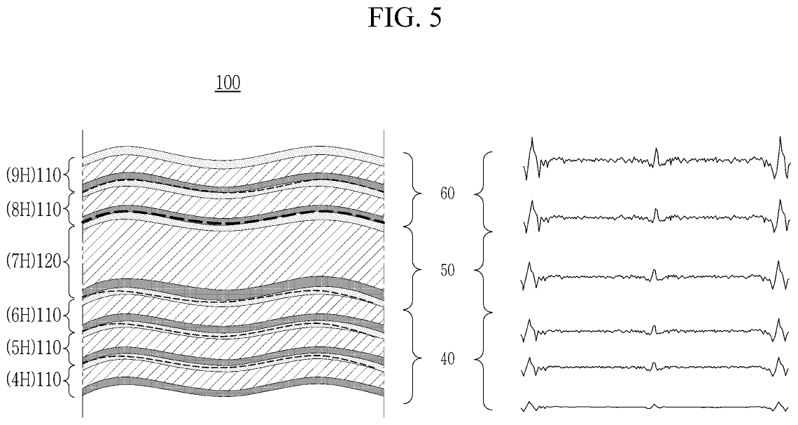

FIG. 5 is a cross-sectional view illustrating the HBM in which 8H-semiconductor chip dies 120 are interposed between the stacked 12H-semiconductor chip dies 110 according to an embodiment, and a graph illustrating deviation values of surface topography corresponding to each 12H-semiconductor chip die 110 and 8H-semiconductor chip die 120 in the HBM in which the 8H-semiconductor chip dies 120 are interposed between the stacked 12H-semiconductor chip dies 110. In FIG. 5, for convenience, six 12H-semiconductor chip dies 110 from the 1H layer to the 3H layer and the 10H to 12H layers are not illustrated.

Referring to FIG. 5, the HBM 100 includes six 12H-semiconductor chip dies 110 having a vertical thickness of 38 μm from the 1H layer to the 6H layer, and an 8H-semiconductor chip die 120 having a vertical thickness of 55 um in the 7H layer, and again, include five 12H-semiconductor chip dies 110 having a vertical thickness of 38 μm from the 8H layer to the 12H layer. Looking at the surface topography deviation graph corresponding to the semiconductor chip stack, it can be seen that in the low-stage stack 40 of the 12H-semiconductor chip dies 110 from the 4H layer to the 6H layer, the deviation of the surface topography is accumulated and gradually increases, but in the 7H layer 50, the 8H-semiconductor chip die 120 having a vertical thickness of 55 μm is interposed to mitigate the accumulation of deviations in surface topography, and in the high-stage stacks 60 of the 12H-semiconductor chip dies 110 of the 8H layer and the 9H layer, the increase in surface topography deviation due to accumulation is mitigated.

In this way, in the HBM 100 in which the 12H-semiconductor chip dies 110 are stacked, when the 8H-semiconductor chip die 120 is included between the 12H-semiconductor chip dies 110, it is possible to mitigate the increase in surface topography due to accumulation, and to prevent formation of the stack voids 30 caused by an increase in accumulated surface topography in the 12H-semiconductor chip stack.

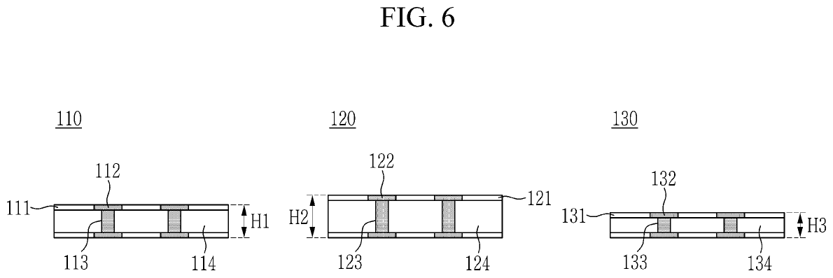

FIG. 6 is a cross-sectional view illustrating cross-sections of the 12H-semiconductor chip die 110, the 8H-semiconductor chip die 120, and the 16H-semiconductor chip 130 according to an embodiment.

Referring to FIG. 6, the 12H-semiconductor chip die 110 may include a silicon insulation layer 111, a bonding pad 112, a TSV 113 and a DRAM 114.

Based on the wafer, the silicon insulation layer 111 may be formed on an upper surface of the DRAM 114, on a lower surface of the DRAM 114, or both on the upper surface and the lower surface of the DRAM 114.

The silicon insulation layer 111 formed on the DRAM 114 may be deposited by chemical vapor deposition (CVD), atomic layer deposition (ALD), plasma enhanced chemical vapor deposition (PECVD), or other methods, after forming the bonding pad 112.

The silicon insulation layer 111 formed under the DRAM 114 may be deposited through chemical vapor deposition (CVD), atomic layer deposition (ALD), plasma enhanced chemical vapor deposition (PECVD), or other methods, after performing a thin film process on the backside of the wafer and then forming the bonding pads 112.

The silicon insulation layer 111 may include silicon oxide (SiO₂). In other embodiments, the silicon insulation layer 111 may be silicon nitride, silicon oxynitride, or other suitable dielectric material.

Based on the wafer, the bonding pad 112 may be formed on an upper surface of the DRAM 114 or a lower surface of the DRAM 114, or on both of an upper surface and a lower surface of the DRAMs 114. The bonding pad 112 may be formed on the same level as the silicon insulation layer 111.

The bonding pad 112 formed on the DRAM 114 may be formed by sputtering after performing photoresist deposition, photomask deposition, exposure, development, and etching. In another embodiment, the bonding pad 112 may be formed by electroplating after performing photoresist deposition, photomask deposition, exposure, development, and etching. The bonding pad 112 may be formed by first forming a seed metal layer and then growing a metal film from the seed metal layer by electroplating. In one embodiment, an annealing process may be performed after the bonding pad 112 is formed.

The bonding pad 112 on a lower surface of the DRAM 114 may be formed by performing a metal filling process after performing photoresist deposition, photomask deposition, exposure, development, and etching after performing a thin film process on the backside of the wafer. The metal filling process for forming the bonding pad 112 under the DRAM 114 may be the same as the metal filling process (sputtering, electroplating or annealing) for forming the bonding pad 112 on the DRAM 114.

The bonding pad 112 may include copper (Cu). However, embodiments are not limited thereto, and the bonding pad 112 may be a metallic material to which hybrid bonding is applicable.

The TSV 113 may be formed through the DRAM 114. In one embodiment, a via hole of the TSV 113 may be formed by deep etching. In another embodiment, the via hole of the TSV 113 may be formed by a laser. In one embodiment, the via hole of TSV 113 may be filled with copper by electroplating.

The 8H-semiconductor chip die 120 may include a silicon insulation layer 121, a bonding pad 122, a TSV 123, and a DRAM 124. The 16H-semiconductor chip die 130 may include a silicon insulation layer 131, a bonding pad 132, a TSV 133, and a DRAM 134. The above description of the silicon insulation layer 111, the bonding pad 112, the TSV 113, and the DRAM 114 of the 12H-semiconductor chip die 110 may be equally applied to the silicon insulation layer 121, the bonding pad 122, the TSV 123, and the DRAM 124 of the 8H-semiconductor chip die 120, and the silicon insulation layer 131, the bonding pad 132, the TSV 133, and the DRAM 134 of 16H-semiconductor chip die 130.

After thinning the backside wafer of the semiconductor chip die, the final 12H-semiconductor chip die 110 may have a vertical thickness H1 of about 38 um. After thinning the backside wafer of the semiconductor chip die, the 8H-semiconductor chip die 120 may have a vertical thickness H2 of about 55 um. After thinning the backside wafer of the semiconductor chip die, the 16H-semiconductor chip die 130 may have a vertical thickness H3 of about 27 um. According to the embodiment, the vertical thickness H2 of the 8H-semiconductor chip die 120 may be greater than the vertical thickness H1 of the 12H-semiconductor chip die 110 or the vertical thickness H3 of the 16H-semiconductor chip die 130. According to the embodiment, the vertical thickness H2 of the 8H-semiconductor chip die 120 may be 10% or more greater than the vertical thickness H1 of the 12H-semiconductor chip die 110 or the vertical thickness H3 of the 16H-semiconductor chip die 130.

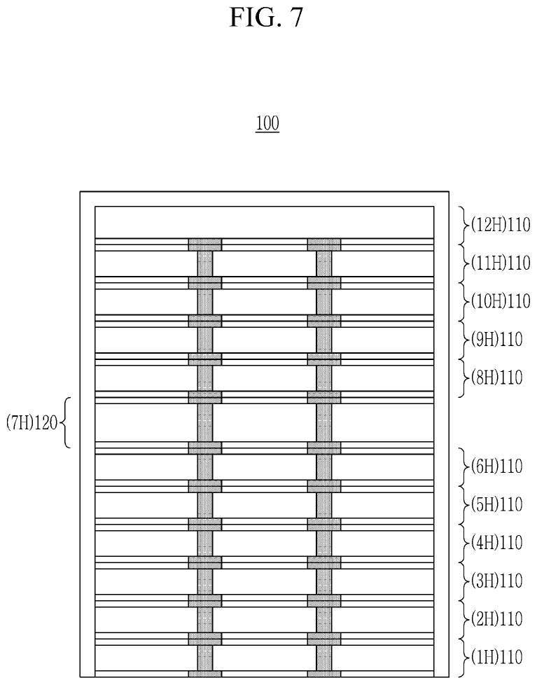

FIG. 7 is a cross-sectional view illustrating the HBM 100 in which the 8H-semiconductor chip dies 120 are interposed between the stacked 12H-semiconductor chip dies 110 according to an embodiment.

Referring to FIG. 7, the HBM 100 may include the 12H-semiconductor chip dies 110 and the 8H-semiconductor chip dies 120 between the 12H-semiconductor chip dies 110. For example, the HBM 100 may be formed by staking the 12H-semiconductor chip dies 110 from the 1H layer to the 6H layer, stacking the 8H-semiconductor chip die 120 on the 7H layer, and stacking the 12H-semiconductor chip dies 110 from the 8H layer to the 12H layer.

As described in FIG. 4, when the 12H-semiconductor chip dies 110 are stacked from the 1H layer to the 7H layer, a stack void 30 may be generated at the boundary between the 12H-semiconductor chip die 110 in the 8H layer and the 12H-semiconductor chip die 110 in the 7H layer. Therefore, when the deviation accumulation of surface topography is mitigated by stacking the 12H-semiconductor chip dies 110 having the vertical thickness of about 38 μm from the 1H layer to the 6H layer and stacking the 8H-semiconductor chip dies 120 having the vertical thickness of about 55 um on the 7H layer, and then the 12H-semiconductor chip dies 110 having the vertical thickness of about 38 μm are stacked again from the subsequent 8H layer to the 12H layer, it is possible to mitigate the increase in deviation of surface topography due to accumulation.

In an embodiment, the HBM 100 may be formed by stacking the 12H-semiconductor chip dies 110 from the 1H layer to the 4H layer, stacking the 8H-semiconductor chip dies 120 in the 5H layer, and stacking the 12H-semiconductor chip dies 110 again from the 6H layer to the 12H layer.

When the 12H-semiconductor chip dies 110 are stacked from the 5H layer to the 12H layer, the stack void 30 may be generated at a boundary between the 12H-semiconductor chip die 110 in the 11H layer and the 12H-semiconductor chip die 110 in the 12H layer. Therefore, when the deviation accumulation of surface topography is mitigated by stacking the 12H-semiconductor chip dies 110 having the vertical thickness of about 38 μm from the 1H layer to the 4H layer and stacking the 8H-semiconductor chip dies 120 having the vertical thickness of about 55 um on the 5H layer, and then the 12H-semiconductor chip dies 110 having the vertical thickness of about 38 μm again are stacked from the subsequent 6H layer to the 12H layer to form the HBM 100, it is possible to mitigate the increase in deviation of surface topography due to accumulation.

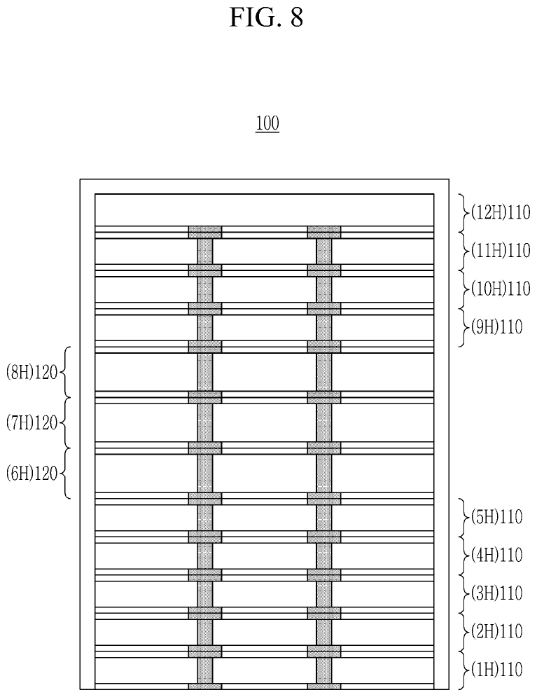

FIG. 8 is a cross-sectional view illustrating the HBM 100 in which a plurality of 8H-semiconductor chip dies 120 are interposed between the stacked 12H-semiconductor chip dies 110 according to an embodiment.

Referring to FIG. 8, the HBM 100 may include the 12H-semiconductor chip dies 110 and the plurality of 8H-semiconductor chip dies 120 between the 12H-semiconductor chip dies 110. For example, the 12H-semiconductor chip dies 110 may be stacked from the 1H layer to the 5H layer, the 8H-semiconductor chip dies 120 may be stacked from the 6H layer to the 8H layer, and the 12H-semiconductor chip dies 110 may be stacked from the 9H layer to the 12H layer.

According to the embodiment of FIG. 8, when the HBM 100 is formed by including the plurality of 8H-semiconductor chip dies 120 having a vertical thickness of about 55 um between the 12H-semiconductor chip dies 110 having a vertical thickness of about 38 um, an increase in surface topography deviation due to accumulation may be more alleviated than in the embodiment of FIG. 7.

When a semiconductor chip die whose vertical thickness is 10% or more greater than the vertical thickness H1 of the 12H-semiconductor chip die 110 or the vertical thickness H3 of the 16H-semiconductor chip die 130 and thinner than 55 um is included between the 12H-semiconductor chip dies 110 or the 16H-semiconductor chip dies 130 when the 12H-semiconductor chip dies 110 or the 16H-semiconductor chip dies 130 are stacked, the semiconductor chip die must be stacked multiple times to obtain a desired surface topography deviation.

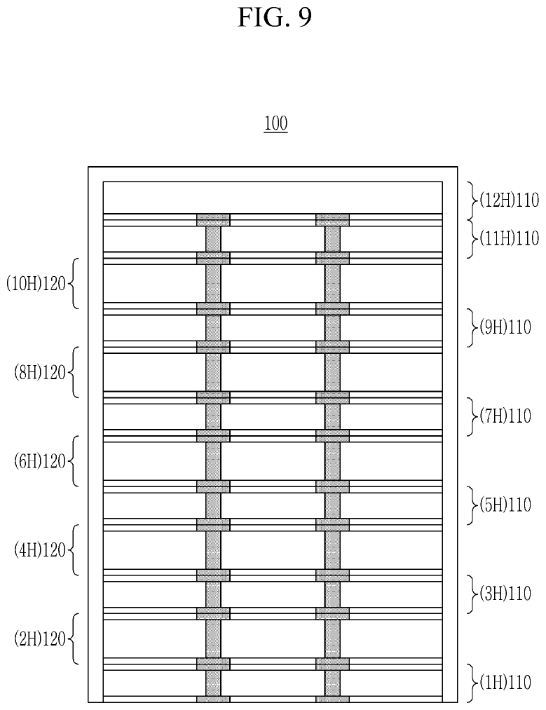

FIG. 9 is a cross-sectional view illustrating the HBM 100 in which the 12H-semiconductor chip dies 110 and the 8H-semiconductor chip dies 120 are alternately stacked according to an embodiment.

Referring to FIG. 9, in the HBM 100, the 8H-semiconductor chip dies 120 may be included between the adjacent 12H-semiconductor chip dies 110. For example, the HBM 100 may be formed by stacking the 12H-semiconductor chip dies 110 in the 1H, 3H, 5H, 7H, 9H, 11H and 12H layers, and stacking the 8H-semiconductor chip dies 120 on the 2H, 4H, and 6H, 8H, and 10H layers.

According to the embodiment of FIG. 9, when the HBM 100 is formed by alternatively stacking the 12H-semiconductor chip dies 110 having a vertical thickness of about 38 um and the 8H-semiconductor chip dies 120 having a vertical thickness of about 55 um, an increase in surface topography deviation due to accumulation may be more alleviated than in the embodiment of FIG. 8.

A method of manufacturing the HBM 100 including the 12H-semiconductor chip dies is described. For reference, a method of manufacturing the HBM 100 including the 16H-semiconductor chip dies is performed in the same manner.

First, before performing the wafer thin film process, a front-side of a first 12H-semiconductor chip die 110 and a front-side of a second 12H-semiconductor chip die 110 are bonded by hybrid bonding.

The bonding pads 112 of the first 12H-semiconductor chip die 110 may be directly bonded to the bonding pads 112 of the second 12H-semiconductor chip die 110 by metal-metal hybrid bonding. Metal bonding is performed at the interface between the bonding pads 112 of the first 12H-semiconductor chip die 110 and the bonding pads 112 of the second 12H-semiconductor chip die 110 by metal-metal hybrid bonding. The bonding pads 112 of the first 12H-semiconductor chip die 110 and the bonding pads 112 of the second 12H-semiconductor chip die 110 are made of the same material, such that after hybrid bonding, an interface between the bonding pads 112 of the first 12H-semiconductor chip die 110 and the bonding pads 112 of the second 12H-semiconductor chip die 110 may disappear. Through the bonding pads 112 of the first 12H-semiconductor chip die 110 and the bonding pads 112 of the second 12H-semiconductor chip die 110, the first 12H-semiconductor chip die 110 and the second 12H-semiconductor chip die 110 may be electrically connected to each other.

The silicon insulation layer 111 of the first 12H-semiconductor chip die 110 may be directly bonded to the silicon insulation layer 111 of the second 12H-semiconductor chip die 110 by non-metal-non-metal hybrid bonding. Covalent bonding is made at the interface between the silicon insulation layer 111 of the first 12H-semiconductor chip die 110 and the silicon insulation layer 111 of the second 12H-semiconductor chip die 110 by non-metal-non-metal hybrid bonding. The silicon insulation layer 111 of the first 12H-semiconductor chip die 110 and the silicon insulation layer 111 of the second 12H-semiconductor chip die 110 are made of the same material, so that after hybrid bonding, an interface between the silicon insulation layer 111 of the first 12H-semiconductor chip die 110 and the second 12H-semiconductor chip die 110 may disappear.

Then, the backside wafer of the second 12H-semiconductor chip dies 110 is thinned by a thin film process. Thereafter, through-holes are formed on the backside of the second 12H-semiconductor chip dies 110 by using a laser or by performing deep etching, and the TSV 113 is formed by filling the through-holes with metal (for example, copper). Next, the bonding pads 112 and the silicon insulation layers 111 are formed in the direction of the backside of the second 12H-semiconductor chip dies 110. Thereafter, the backside of the second 12H-semiconductor chip dies 110 and the front side of the third 12H-semiconductor chip dies 110 are bonded by hybrid bonding. By repeating this process, the 12H-semiconductor chip dies 110 may be stacked from the 1H layer to the 12H layer.

The HBM 100 may include a base die at the lowermost end. In the embodiment, in the HBM 100, a base die may be omitted. The HBM 100 may include a 12H-semiconductor chip die of the 12H layer thicker than the 12H-semiconductor chip dies of the 1H to 11H layers at the uppermost end. The vertical height of the HBM 100 increased by including the 8H-semiconductor chip dies 120 having a vertical thickness of 55 um between the 12H-semiconductor chip dies 110 having a vertical thickness of about 38 um according to embodiments may be adjusted by the method of decreasing the vertical thickness of the 12H-semiconductor chip die of the 12H layer, which is thicker than the 12H-semiconductor chip die of the 1H layer to the 11H layer, at the uppermost end.

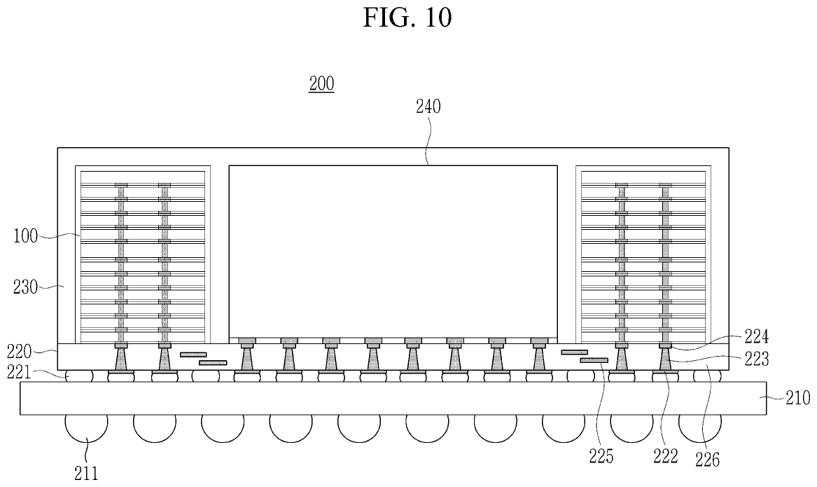

FIG. 10 is a cross-sectional view of a 2.5D semiconductor package 200 including the HBM 100 according to an embodiment.

The 2.5D semiconductor package 200 may include a printed circuit board (PCB) 210, a silicon interposer 220, a high-bandwidth memory (HBM) 100, a logic circuit (semiconductor chip) 240, and an encapsulant 230.

The printed circuit board (PCB) 210 may be electrically coupled with an external device by being bonded to an external connection terminal 211. In the embodiment, the external connection terminal 211 may include a solder ball. In the embodiment, the external connection terminal 211 may include tin (Sn) and lead (Pb).

The silicon interposer 220 may include metal vias 223, bonding pads 222 and 224, redistribution lines 225, and a silicon insulation layer 226. The metal vias 223 and the redistribution lines 225 may be connected and electrically coupled to the bonding pads 222 and 224. The bonding pads 222 may be connected and electrically coupled to a connection member 221. The bonding pads 224 may be connected and electrically coupled to the HBM 100 and the logic circuit 240 by hybrid bonding.

The connection member 221 may be bonded to the bonding pad 222 of the silicon interposer 220 to electrically couple the printed circuit board (PCB) 210 and the silicon interposer 220. In the embodiment, the connection member 221 may include a solder ball. In the embodiment, the connection member 221 may include tin (Sn) and lead (Pb). In another embodiment, the connection member 221 may include tin (Sn), bismuth (Bi), silver (Ag), copper (CU), or an alloy thereof.

The HBM 100 includes the 12H-semiconductor chip dies 110 and the 8H-semiconductor chip dies 120 between the 12H-semiconductor chip dies 110 according to an embodiment. In addition, the HBM 100 may include the 16H-semiconductor chip dies 130 and the 8H-semiconductor chip dies 120 between the 16H-semiconductor chip dies 130 according to the present disclosure. In addition, the HBM 100 may include the 16H-semiconductor chip dies 130 and the 12H-semiconductor chip dies 110 between the 16H-semiconductor chip dies 130 according to an embodiment.

The logic circuit 240 may be disposed side-by-side with the HBMs 100 between the HBMs 100. In an embodiment, the logic circuit 240 may include a central processing unit (CPU) or a graphic processing unit (GPU).

The encapsulant 230 may mold the HBMs 100 and the logic circuit 240 on the silicon interposer 220. In an embodiment, the encapsulant 230 may include an epoxy molding compound (EMC).

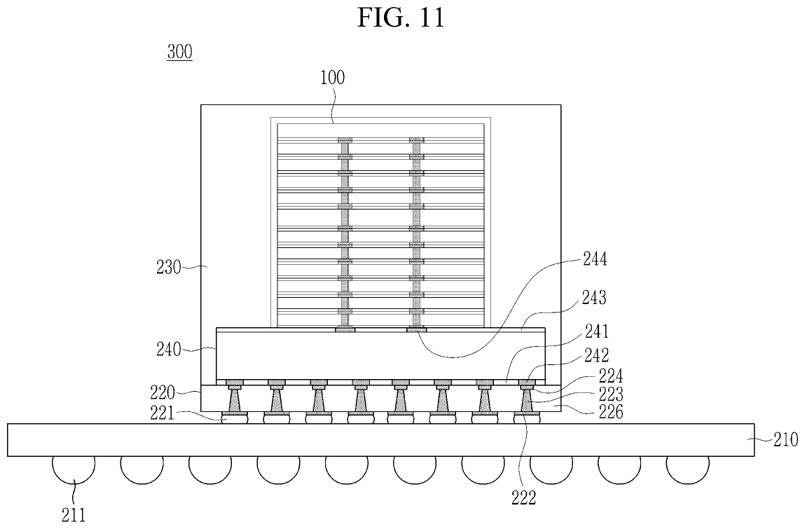

FIG. 11 is a cross-sectional view illustrating a cross-section of a 3D semiconductor package including the HBM according to an embodiment.

The 3D semiconductor package 300 of FIG. 11 may include a printed circuit board (PCB) 210, a silicon interposer 220, a high-bandwidth memory (HBM) 100, a logic circuit 240, an encapsulant 230, and an external connection terminal 211, and a connection member 221, and the silicon interposer 220 may include metal vias 223, bonding pads 222 and 224, and a silicon insulation layer 226, but the same characteristics of the components of the 2.5D semiconductor package 200 of FIG. 10 may be applied to the corresponding components.

Referring to FIG. 11, the semiconductor package 300 may include the logic circuit 240 mounted on the silicon interposer 220 and the HBM 100 mounted on the logic circuit 240. In FIG. 11, the silicon interposer 220, the logic circuit 240, and the HBM 100 may be vertically disposed. In this case, the silicon interposer 220, the logic circuit 240, and the HBM 100 may be connected to each other by hybrid bonding and electrically coupled to each other. The silicon insulation layer 241 of the logic circuit 240 may be connected to the silicon insulation layer 226 of the interposer 220 by hybrid bonding and electrically coupled thereto. Bonding pads 242 of the logic circuit 240 may be connected to bonding pads 224 of the interposer 220 by hybrid bonding and electrically coupled thereto. The silicon insulation layer 243 of the logic circuit 240 is connected to the silicon insulation layers 111 and 131 of the semiconductor chip dies 110 and 130 of the HBM 100 by hybrid bonding and electrically coupled thereto. The bonding pads 243 of the logic circuit 240 are connected to the bonding pads 112 and 132 of the semiconductor chip dies 110 and 130 of the HBM 100 by hybrid bonding and are electrically coupled thereto.

According to embodiments, the 12H-semiconductor chip stack and the 8H-semiconductor chip stack have been mainly described, but embodiments are not limited thereto, and other configurations, such as a 16H-semiconductor chip stack, may be included within the scope of the present disclosure.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor chip stack structure comprising:
a plurality of first semiconductor chip dies stacked in a vertical direction; and
one or more second semiconductor chip dies between adjacent first semiconductor chip dies among the plurality of first semiconductor chip dies,
wherein a thickness of each second semiconductor chip die of the one or more second semiconductor chip dies is greater than a thickness of each first semiconductor chip die of the plurality of first semiconductor chip dies in the vertical direction.

2. The semiconductor chip stack structure of claim 1, wherein each of the plurality of first semiconductor chip dies and each of the one or more second semiconductor chip dies are alternately stacked.

3. The semiconductor chip stack structure of claim 1, wherein the thickness of the second semiconductor chip die is 10% or more greater than the thickness of the first semiconductor chip die and is smaller than 55 um.

4. The semiconductor chip stack structure of claim 1, wherein a number of stacked layers of the plurality of first semiconductor chip dies and the one or more second semiconductor chip dies is 12.

5. The semiconductor chip stack structure of claim 4, wherein a fifth layer or a seventh layer from a lowest layer of the stacked layers comprises the one or more second semiconductor chip dies.

6. A semiconductor package comprising:
an interposer;
a plurality of semiconductor chip stack structures on the interposer, each semiconductor chip stack structure of the plurality of semiconductor chip stack structures comprising a plurality of first semiconductor chip dies stacked in a vertical direction, and one or more second semiconductor chip dies between adjacent first semiconductor chip dies among the plurality of first semiconductor chip dies;
a third semiconductor chip on the interposer; and
an encapsulant on the interposer, the plurality of semiconductor chip stack structures, and the third semiconductor chip,
wherein a thickness of each second semiconductor chip die of the one or more second semiconductor chip dies is greater than a thickness of each first semiconductor chip die of the plurality of first semiconductor chip dies in the vertical direction.

7. The semiconductor package of claim 6, wherein the third semiconductor chip is adjacent to the plurality of semiconductor chip stack structures in a horizontal direction.

8. The semiconductor package of claim 6, wherein the third semiconductor chip is between the plurality of semiconductor chip stack structures and the interposer.

9. The semiconductor package of claim 6, wherein the plurality of semiconductor chip stack structures comprises a high bandwidth memory (HBM).

10. The semiconductor package of claim 6, wherein the third semiconductor chip comprises a central processing unit (CPU) or a graphic processing unit (GPU).

11. The semiconductor package of claim 6, wherein the encapsulant comprises an epoxy molding compound (EMC).

12. A semiconductor package comprising:
a substrate;
an interposer on the substrate;
a plurality of connection members electrically connecting the substrate and the interposer;
a plurality of semiconductor chip stack structures directly on the interposer, each of the semiconductor chip stack structures of the plurality of semiconductor chip stack structures comprising a plurality of first semiconductor chip dies stacked in a vertical direction, and one or more second semiconductor chip dies between adjacent first semiconductor chip dies among the plurality of first semiconductor chip dies;
a third semiconductor chip on the interposer; and
an encapsulant on the interposer, the plurality of semiconductor chip stack structures, and the third semiconductor chip,
wherein a thickness of each second semiconductor chip die of the one or more second semiconductor chip dies is greater than a thickness of each first semiconductor chip die of the plurality of first semiconductor chip dies in the vertical direction.

13. The semiconductor package of claim 12, wherein the first semiconductor chip die comprises a plurality of first bonding pads and a first insulating layer at a same level as the plurality of first bonding pads on at least one of an upper surface of the first semiconductor chip die and a lower surface of the first semiconductor chip die in a horizontal direction, and
wherein the second semiconductor chip die comprises a plurality of second bonding pads and a second insulating layer at a same level as the plurality of second bonding pads on each of an upper surface of the second semiconductor chip die and a lower surface of the second semiconductor chip die in the horizontal direction.

14. The semiconductor package of claim 13, wherein each first bonding pad of a plurality of first bonding pads of the first semiconductor chip die or each second bonding pad of a plurality of second bonding pads of the second semiconductor chip die is directly on each first bonding pad of a plurality of first bonding pads of an adjacent first semiconductor chip die or each second bonding pad of a plurality of second bonding pads of an adjacent second semiconductor chip die.

15. The semiconductor package of claim 14, wherein the first insulating layer included in the first semiconductor chip die or the second insulating layer included in the second semiconductor chip die is directly on a first insulating layer of an adjacent first semiconductor chip die or a second insulating layer of an adjacent second semiconductor chip die.

16. The semiconductor package of claim 13, wherein the interposer comprises a silicon interposer.

17. The semiconductor package of claim 16, wherein the silicon interposer comprises a plurality of third bonding pads and a third insulating layer.

18. The semiconductor package of claim 17, wherein each third bonding pad of the plurality of third bonding pads included in the silicon interposer is directly on each first bonding pad of the plurality of first bonding pads on a lower surface of the first semiconductor chip die at a lowermost end of the plurality of first semiconductor chip dies of each semiconductor chip stack structure of the plurality of semiconductor chip stack structure, and
wherein a third insulating layer included in the silicon interposer is directly on the first insulating layer of the lower surface of the first semiconductor chip die at the lowermost end.

19. The semiconductor package of claim 13, wherein the first insulation layer and the second insulation layer comprise silicon oxide.

20. The semiconductor package of claim 13, wherein the plurality of first bonding pads and the plurality of second bonding pads comprise copper (Cu).
